(19) United States
(12) Patent Application Publication
(10) Pub. No.: US 2010/0119982 A1
(43) Pub. Date: May 13, 2010

(54) ETCHING METHOD AND MANUFACTURING METHOD OF SEMICONDUCTOR DEVICE

(76) Inventor: Koutarou SHO, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/558,620

(22) Filed: Sep. 14, 2009

(30) Foreign Application Priority Data
Nov. 10, 2008 (JP) 2008-287384

(51) Int. Cl. G03F 7/20

(52) U.S. Cl. 430/319; 430/325

(57) ABSTRACT

An etching method according to an embodiment includes forming a resist film on a workpiece film, exposing the resist film, developing the resist film so as to form a resist pattern, selectively irradiating a particular place of the resist pattern with an energy beam so as to generate an acid component in the particular place of the resist pattern, forming a film including a cross-linking agent that causes a cross-linking reaction due to the acid component on the workpiece film so as to cover the particular place of the resist pattern where the acid component is generated, reacting the cross-linking agent with the resist pattern so as to form a cross-linked layer in a part of the resist pattern and processing the workpiece film by using the resist pattern and the cross-linked layer as a mask.

### CROSS-REFERENCE TO RELATED APPLICATIONS

This application is based upon and claims the benefit of priority from prior Japanese Patent Application No. 2008-287384, filed on Nov. 10, 2008, the entire contents of which are incorporated herein by reference.

### BACKGROUND

Recently, in accordance with miniaturization of a semiconductor element, a method capable of forming a resist pattern with a high degree of accuracy is required. As the above-mentioned technology, a method of forming a resist pattern that includes forming a cross-linked layer on the surface thereof is disclosed, for example, in a patent literature of JP-A-1998(H10)-73927.

According to the method of forming the resist pattern described in the patent literature, a first resist is coated on a semiconductor substrate and the first resist is exposed through a mask, so as to form a first resist pattern. Next, a second resist is coated on the semiconductor substrate so as to cover the first resist pattern, a selected region of the semiconductor substrate is shielded by an electron beam shield plate, and regions other than the selected region are irradiated with an electron beam. An acid component is generated from the first resist pattern due to the electron beam irradiation, a cross-linking reaction is caused in an interface between the second resist pattern and the first resist pattern, and the first resist pattern is covered with a cross-linked layer. By this, an etching resistance of the whole of the first resist pattern is enhanced. Further, since the first resist pattern is selectively irradiated with the electron beam so as to form the cross-linked layer by cross-linking the second resist pattern at the place where the electron beam is not irradiated, a dimension of the resist pattern can be selectively controlled.

### BRIEF SUMMARY

An etching method according to an embodiment includes forming a resist film on a workpiece film, exposing the resist film, developing the resist film so as to form a resist pattern, selectively irradiating a particular place of the resist pattern with an energy beam so as to generate an acid component in the particular place of the resist pattern, forming a film including a cross-linking agent that causes a cross-linking reaction due to the acid component on the workpiece film so as to cover the particular place of the resist pattern where the acid component is generated, reacting the cross-linking agent with the resist pattern so as to form a cross-linked layer in a part of the resist pattern and processing the workpiece film by using the resist pattern and the cross-linked layer as a mask.

A manufacturing method of a semiconductor device according to another embodiment includes forming a resist film on a workpiece film, exposing the resist film, developing the resist film so as to form a resist pattern, selectively irradiating a particular place of the resist pattern with an energy beam so as to generate an acid component in the particular place of the resist pattern, forming a film including a cross-linking agent that causes a cross-linking reaction due to the acid component on the workpiece film so as to cover the particular place of the resist pattern where the acid component is generated, reacting the cross-linking agent with the resist pattern so as to form a cross-linked layer in a part of the resist pattern, and processing the workpiece film by using the resist pattern and the cross-linked layer as a mask.

### BRIEF DESCRIPTION OF THE DRAWING

FIGS. 1A to 1H are cross-sectional views sequentially showing a manufacturing process of a semiconductor device according to the first embodiment;

FIG. 2A is a plan view of FIG. 1G;

FIG. 2B is a plan view of FIG. 1H;

FIG. 3A is a cross-sectional view showing a state before an etching process as a comparative example;

FIG. 3B is a plan view showing a state before an etching process as a comparative example;

FIG. 3C is a cross-sectional view showing a state after an etching process as a comparative example; and

FIG. 3B is a plan view showing a state after an etching process as a comparative example.

### DETAILED DESCRIPTION

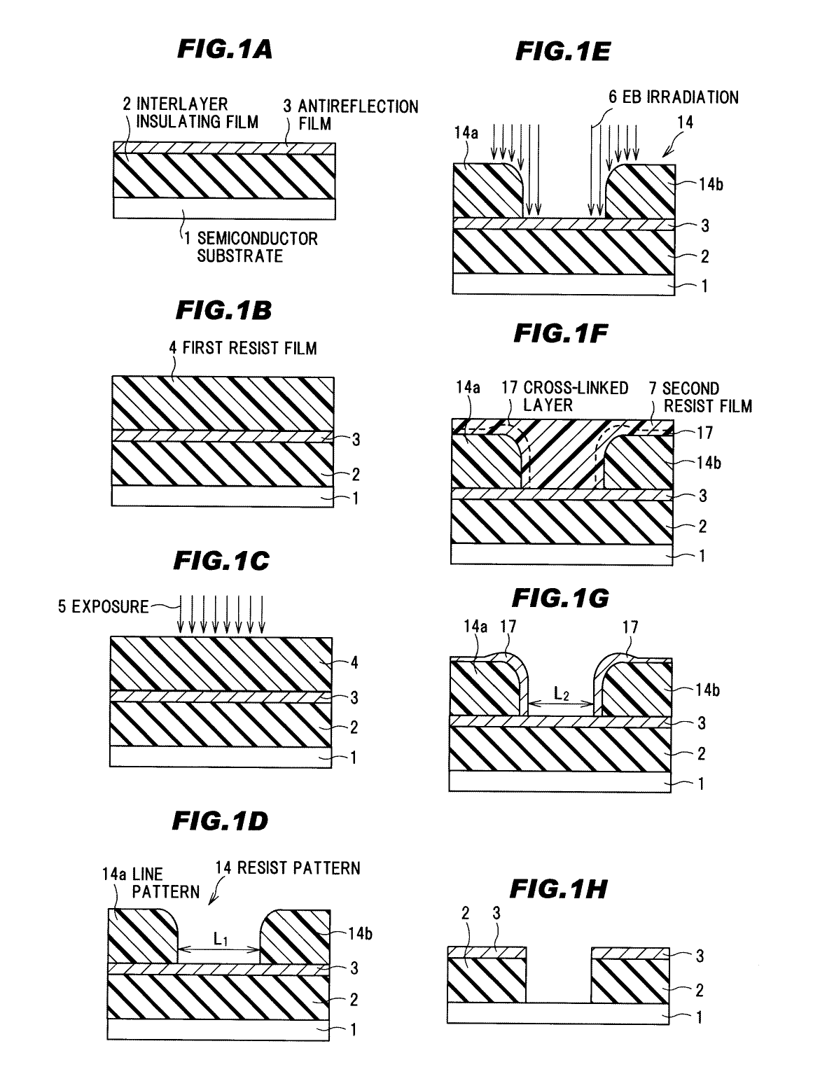

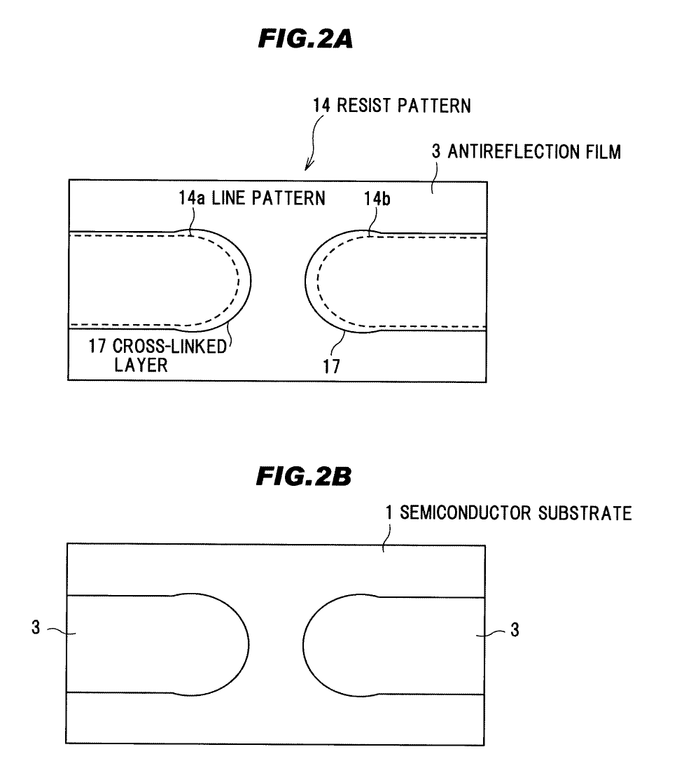

FIGS. 1A to 1H are cross-sectional views sequentially showing a manufacturing process of a semiconductor device according to the first embodiment, FIG. 2A is a plan view of FIG. 1G and FIG. 2B is a plan view of FIG. 1H. Hereinafter, a case will be explained as an example, that a resist pattern where line patterns are disposed in a longitudinal direction is formed.

As shown in FIG. 1A, an interlayer insulating film 2 formed of a silicon oxide film or the like is formed on a semiconductor substrate 1 such as a silicon substrate, an antireflection film 3 is coated on the interlayer insulating film 2 by a spin coat so as to have a film thickness of 80 nm, and then a baking treatment is carried out at 205 degrees C., for 60 seconds in order to volatilize a solvent.

Next, as shown in FIG. 1B, a first resist film 4 is coated on the antireflection film 3 by a spin coat so as to have a film thickness of 150 nm, and then the baking treatment is carried out at 130 degrees C., for 60 seconds. As the first resist film 4, both of a positive type resist film and a negative type resist film can be used. The first resist film 4 is formed of a material for generating the acid component due to an irradiation of an energy beam such as an electron beam, and in the embodiment, ArF positive type resist film is used.

Next, as shown in FIG. 1C, the first resist film 4 is irradiated with ArF excimer laser through a half tone mask having a transmittance of 6% so as to carry out an exposure by using an ArF excimer laser exposure device (AS4: manufactured by Canon Inc.) and under the conditions of NA=0.85, σ=0.90 and ¾ annular illumination.

Next, as shown in FIG. 1D, after a baking treatment is carried out at 130 degrees C. and for 90 seconds in order to accelerate a reaction between the acid generated by the exposure and an elimination group, a puddle development using 2.38 wt % aqueous solution of tetramethylammonium hydroxide is carried out for 30 seconds so as to form the resist pattern 14 having a space length L1 which is, for example, 30 to 40 nm in the longitudinal direction between the line patterns 14a, 14b.

Next, after a particular place is extracted, where a remaining film of the resist pattern 14 after the development has a film thickness of a certain thickness (for example, 10 nm), as shown in FIG. 1E, an electron beam (EB) irradiation 6 is carried out selectively to the particular place. By the EB irradiation 6, an acid component is generated in the resist pattern 14. Further, the particular place can be extracted as a place where the process conversion difference is not less than a certain value based on the process conversion difference rule. Here, the “process conversion difference” means a difference between a dimension of the workpiece film pattern after the workpiece film of a lower layer is etched by using the resist pattern as a mask and a dimension of the resist pattern. The “process conversion difference rule” means a table or a function which makes a correlation between a dimension of the pattern after the etching and a dimension of the resist pattern based on a contour shape of the pattern. An energy beam irradiation such as an UV irradiation, an X-ray irradiation can be also used as well as the EB irradiation 6.

Next, as shown in FIG. 1F, after a second resist film 7 is coated on the antireflection film 3 by the spin coat so as to cover the resist pattern 14 and have a film thickness (a thickness on the interlayer insulating film 2) of 300 nm, a baking treatment is carried out at 120 degrees C., for 60 seconds in order to cause a cross-linking reaction. As the second resist film 7, a resist film containing a cross-linking agent, for example, RELACS (registered trademark) manufactured by Clariant Japan can be used. The cross-linking agent reacts with the acid component generated from the resist pattern 14 so as to form a cross-linked layer 17.

Next, as shown in FIG. 1G, a rinse treatment is carried out by using pure water for 60 seconds so as to eliminate some part other than the cross-linked layer 17 of the second resist film 7 (not cross-linked part) and form the cross-linked layer 17 on a surface of the resist pattern 14. A space length L2 shrinks by almost 5 to 20 nm than the space length L1 shown in FIG. 1D. As shown in FIG. 2, the cross-linked layer 17 is formed on the periphery of the resist part irradiated with the energy beam so that the resist pattern 14 having line patterns 14a, 14b of not more than 50 nm in width is formed without causing a pattern falling.

After that, as shown in FIG. 1H, the antireflection film 3 and the interlayer insulating film 2 are etched by using the cross-linked layer 17 and the resist pattern 14 as a mask.

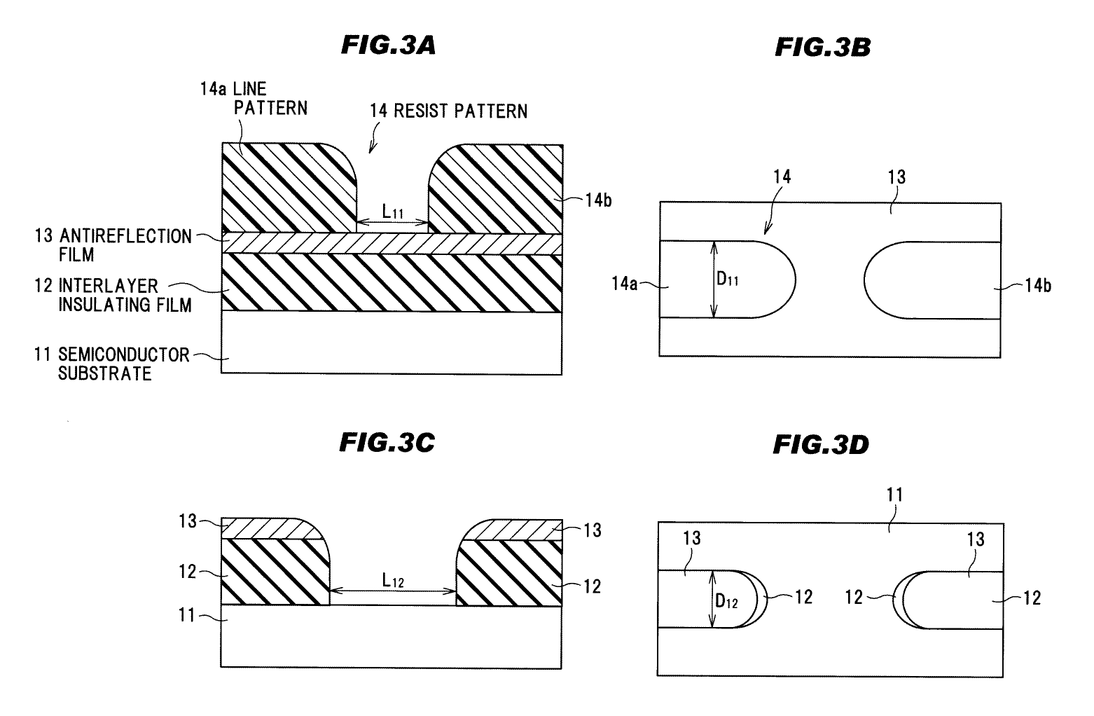

FIG. 3A is a cross-sectional view showing a state before an etching process as a comparative example, FIG. 3B is a plan view showing a state before an etching process as a comparative example, FIG. 3C is a cross-sectional view showing a state after an etching process as a comparative example and FIG. 3B is a plan view showing a state after an etching process as a comparative example.

FIGS. 3A, 3B shows a state obtained by that an interlayer insulating film 12 are formed on a semiconductor substrate 11, a antireflection film 13 is formed on the interlayer insulating film 12, and then a resist pattern 14 having line patterns 14a, 14b in a butted state is formed on the antireflection film 13. The resist pattern 14 does not have the cross-linked layer for being formed on the surface thereof, so that when the antireflection film 13 and the interlayer insulating film 12 are etched by using the resist pattern 14, as shown in FIGS. 3C and 3D, the space length L11 between the line patterns is lengthened to the space length L12 and the line width D11 is narrowed to the line width D12.

As explained above, according to the embodiment, the resist pattern whose dimension is selectively and appropriately controlled can be formed, so that the pattern falling can be prevented and a fine line pattern having a width of not more than 50 nm can be formed. Further, the line patterns 14a, 14b are directly irradiated with the electron beam, so that acid generation efficiency can be enhanced in comparison with a case that the electron beam is irradiated after the second resist film 7 is formed. On the other hand, in a case of a method that the resist pattern is selectively irradiated with the electron beam and the cross-linked layer is formed on the places where the electron beam is not irradiated, acid is generated in a part irradiated with the electron beam so that the cross-linked layer can not be formed in such a desired place as the place in the embodiment.

Further, it should be noted that the present invention is not intended to be limited to the above-mentioned embodiments, and the various kinds of changes thereof can be implemented by those skilled in the art without departing from the gist of the invention. For example, in the embodiment, the resist pattern 14 where line patterns are disposed in the longitudinal direction is explained, however, the present invention can be also applied to the other patterns such as a contact pattern formed of a plurality of contact holes, a line and space where a line and a space are repeated at a certain pitch and the like.

Further, it can be also used that particular places of the resist pattern are irradiated with an energy beam and simultaneously, a region including the particular places is heated, and furthermore, it can be also used that the particular places are heated before or after the particular places are irradiated with an energy beam. By this, the cross-linking reaction can be accelerated.

Further, when the particular places of the resist pattern are irradiated with the energy beam, it can be carried out by using a mask.

Furthermore, in the embodiment, the interlayer insulating film is processed by using the cross-linked layer and the resist pattern as a mask, however, as the workpiece film, materials other than the insulating film such as polysilicon, metal or the like can be also used. A case that polysilicon or metal is used as the workpiece film can be applied to a butted state of SRAM or CMOS, namely, a pair of gate lines where line patterns are disposed in the longitudinal direction.

What is claimed is:

1. An etching method, comprising:
forming a resist film on a workpiece film;
exposing the resist film;
developing the resist film so as to form a resist pattern;
selectively irradiating a particular place of the resist pattern with an energy beam so as to generate an acid component in the particular place of the resist pattern;
forming a film including a cross-linking agent that causes a cross-linking reaction due to the acid component on the workpiece film so as to cover the particular place of the resist pattern where the acid component is generated;
reacting the cross-linking agent with the resist pattern so as to form a cross-linked layer in a part of the resist pattern; and
processing the workpiece film by using the resist pattern and the cross-linked layer as a mask.

2. The etching method according to claim 1, wherein the particular place of the resist pattern is a place of the resist pattern particularly formed so as to be have a film thickness of not more than a certain film thickness.

3. The etching method according to claim 1, wherein the acid component is generated in the particular place of the resist pattern by heating a region including the particular place of the resist pattern.

4. A manufacturing method of a semiconductor device, comprising:
forming a resist film on a workpiece film;
exposing the resist film;
developing the resist film so as to form a resist pattern;
selectively irradiating a particular place of the resist pattern with an energy beam so as to generate an acid component in the particular place of the resist pattern;
forming a film including a cross-linking agent that causes a cross-linking reaction due to the acid component on the workpiece film so as to cover the particular place of the resist pattern where the acid component is generated;
reacting the cross-linking agent with the resist pattern so as to form a cross-linked layer in a part of the resist pattern; and
processing the workpiece film by using the resist pattern and the cross-linked layer as a mask.

5. The manufacturing method of a semiconductor device according to claim 4, wherein the particular place of the resist pattern is a place of the resist pattern particularly formed so as to be have a film thickness of not more than a certain film thickness.

6. The manufacturing method of a semiconductor device according to claim 5, wherein the not more than a certain film thickness is not more than 100 nm.

7. The manufacturing method of a semiconductor device according to claim 4, wherein the particular place of the resist pattern is a place of the resist pattern particularly formed so as to be have a process conversion difference of not less than a certain value when the workpiece film is processed by using the resist pattern as a mask.

8. The manufacturing method of a semiconductor device according to claim 4, wherein the acid component is generated in the particular place of the resist pattern by heating a region including the particular place of the resist pattern.

9. The manufacturing method of a semiconductor device according to claim 4, wherein the selective irradiation to the particular place of the resist pattern with the energy beam is a selective irradiation to the particular place of the resist pattern with an electron beam.

10. The manufacturing method of a semiconductor device according to claim 4, wherein the selective irradiation to the particular place of the resist pattern with the energy beam is carried out by using a mask.

11. The manufacturing method of a semiconductor device according to claim 4, wherein the resist film is a ArF resist film.

12. The manufacturing method of a semiconductor device according to claim 4, wherein the resist pattern is a pair of resist patterns where line patterns are disposed in a longitudinal direction.

13. The manufacturing method of a semiconductor device according to claim 4, wherein the resist pattern is a contact pattern.

14. The manufacturing method of a semiconductor device according to claim 4, wherein the resist pattern is a line and space pattern where lines and spaces are repeated at a certain pitch.

15. The manufacturing method of a semiconductor device according to claim 14, wherein the line and space pattern has a width of not more than 50 μm.

16. The manufacturing method of a semiconductor device according to claim 4, wherein the film including the cross-linking agent that causes the cross-linking reaction due to the acid component is a resist film formed of a different material from the resist film formed on the workpiece film.

17. The manufacturing method of a semiconductor device according to claim 4, wherein the workpiece film is an interlayer insulating film.

18. The manufacturing method of a semiconductor device according to claim 17, wherein the workpiece film is the interlayer insulating film which has an antireflection film formed on a surface thereof where the resist film is formed.

19. The manufacturing method of a semiconductor device according to claim 4, wherein the workpiece film is formed of polysilicon or metal.

20. The manufacturing method of a semiconductor device according to claim 19, wherein the workpiece film is processed so as to form a pair of gate wires where the line patterns are disposed in a longitudinal direction.
